(19) United States
(12) Patent Application Publication
(10) Pub. No.: US 2026/0239606 A1
(43) Pub. Date: Aug. 13, 2026

(54) SEMICONDUCTOR DEVICE

(71) Applicant: SAMSUNG ELECTRONICS CO., LTD., Suwon-si (KR)

(72) Inventors: Hyebin KIM, Suwon-si (KR); Jinwoo HAN, Suwon-si (KR); Woochul KIM, Suwon-si (KR); Gyuhwan OH, Suwon-si (KR); Eunsuk JANG, Suwon-si (KR); Jihoon CHOI, Suwon-si (KR)

(73) Assignee: SAMSUNG ELECTRONICS CO., LTD., Suwon-si (KR)

(21) Appl. No.: 19/339,515

(22) Filed: Sep. 25, 2025

(30) Foreign Application Priority Data
Feb. 10, 2025 (KR) 10-2025-0016915

(51) Int. Cl. H10B 12/00; H10D 1/68

(52) U.S. Cl. CPC H10B 12/482; H10B 12/03; H10B 12/488; H10D 1/714

(57) ABSTRACT

A semiconductor device includes a substrate, a semiconductor pattern extending in a first direction parallel to the substrate, a word line crossing the semiconductor pattern in a second direction, and a bit line connected to one end of the semiconductor pattern and extending in a third direction perpendicular to the substrate. A data storage element is connected to another end of the semiconductor pattern. The bit line includes a first portion connected to the semiconductor pattern and a second portion extending in the first direction from the first portion. A width of the first portion in the second direction is greater than a width of the second portion. This configuration provides sufficient contact area with the semiconductor pattern while reducing electrical coupling between adjacent bit lines.

### CROSS-REFERENCE TO RELATED APPLICATION

This application claims priority to and the benefit of Korean Patent Application No. 10-2025-0016915 filed with the Korean Intellectual Property Office on Feb. 10, 2025, the entire contents of which are incorporated herein by reference.

### BACKGROUND OF THE INVENTION

### (a) Field of the Invention

The present disclosure relates to a semiconductor device.

### (b) Description of the Related Art

Technologies are required to increase the integration density of semiconductor devices. For two-dimensional semiconductor devices, the integration density is mainly determined by the area occupied by the unit memory cell, and this aspect of integration density can be affected by the level of fine pattern formation technology.

However, since the fine pattern formation technology requires expensive equipment, the integration of two-dimensional semiconductor devices is increasing, but is still limited. Accordingly, three-dimensional semiconductor devices having three-dimensionally arranged memory cells are being proposed.

### SUMMARY OF THE INVENTION

The present disclosure attempts to provide a semiconductor device with high reliability.

Additionally, the present disclosure attempts to provide a semiconductor device with improved electrical characteristics.

An embodiment of the present disclosure provides a semiconductor device comprising: a substrate, a semiconductor pattern positioned on the substrate and extending in a first direction parallel to an upper surface of the substrate, a word line positioned on the semiconductor pattern and extending in a second direction, which is parallel to the upper surface of the substrate and intersects the first direction, a bit line connected to one end of the semiconductor pattern and extending in a third direction perpendicular to the upper surface of the substrate, and a data storage element connected to another end of the semiconductor pattern, wherein the bit line comprises a first portion connected to the semiconductor pattern and a second portion extending in the first direction from the first portion, and a width of the first portion in the second direction is greater than a width of the second portion in the second direction.

An embodiment of the present disclosure provides a semiconductor device comprising: a substrate, a first semiconductor pattern and a second semiconductor pattern positioned on the substrate and extending in a first direction parallel to an upper surface of the substrate, a first word line and a second word line extending in a second direction, which is parallel to the upper surface of the substrate and intersects the first direction, and positioned to overlap the first semiconductor pattern and the second semiconductor pattern, respectively, a first bit line to which the first semiconductor pattern and the second semiconductor pattern are connected on opposite sides in the first direction, and a second bit line positioned apart from the first bit line in the second direction, and a pair of first intermediate insulating patterns positioned between the first bit line and the second bit line, and a second intermediate insulating pattern positioned between the pair of first intermediate insulating patterns.

An embodiment of the present disclosure provides a semiconductor device comprising: a substrate, semiconductor patterns positioned on the substrate and extending in a first direction parallel to an upper surface of the substrate, word lines positioned on the semiconductor patterns and extending in a second direction, which is parallel to the upper surface of the substrate and intersects the first direction, a pair of bit lines connected to one end of the semiconductor patterns, extending in a third direction perpendicular to the upper surface of the substrate, and spaced apart from each other in the first direction, and data storage elements connected to another end of the semiconductor patterns, wherein each bit line comprises a first portion positioned on one side of the bit line and connected to the semiconductor patterns stacked in the third direction, and a second portion extending in the first direction from the first portion, and a width of the first portion in the second direction is greater than a width of the second portion in the second direction.

An embodiment of the present disclosure provides a method of manufacturing a semiconductor device, the method comprising: forming a first trench between semiconductor patterns spaced apart from each other in a first direction, forming a first intermediate insulating layer in the first trench, forming a second intermediate insulating layer on the first intermediate insulating layer, patterning the first intermediate insulating layer and the second intermediate insulating layer to form a second trench including a first intermediate insulating pattern, a second intermediate insulating pattern, a first region positioned between the first intermediate insulating pattern, and a second region positioned between the second intermediate insulating pattern, forming a bit line in the second trench, wherein a width of the first region in a second direction is greater than a width of the second region in the second direction.

In a method for manufacturing a semiconductor device according to an embodiment, the first intermediate insulating layer and the second intermediate insulating layer have different etching selectivities.

In a method for manufacturing a semiconductor device according to an embodiment, the first intermediate insulating layer and the second intermediate insulating layer have different compositional ratios.

In a method for manufacturing a semiconductor device according to an embodiment, the first intermediate insulating layer and the second intermediate insulating layer comprise the same insulating material.

In a method for manufacturing a semiconductor device according to an embodiment, the second trench has an H-shaped structure in a plan view.

In a method for manufacturing a semiconductor device according to an embodiment, the first region is positioned on opposite sides of the second trench.

In a method for manufacturing a semiconductor device according to an embodiment, the bit line comprises a first portion formed in the first region and a second portion formed in the second region, and a width of the first portion in the second direction is greater than a width of the second portion in the second direction.

In a method for manufacturing a semiconductor device according to an embodiment, the second trench has a T-shaped structure in a plan view.

In a method for manufacturing a semiconductor device according to an embodiment, the first region is positioned on one side of the second trench.

In a method for manufacturing a semiconductor device according to an embodiment, the step of patterning the first intermediate insulating layer and the second intermediate insulating layer to form the second trench further comprises forming a shield pattern on the second intermediate insulating layer.

In a method for manufacturing a semiconductor device according to an embodiment, the first region of the second trench extends in a third direction, exposing end portions of the semiconductor patterns.

According to embodiments, a semiconductor device with high reliability may be provided.

Further, according to embodiments, a semiconductor device with improved electrical characteristics may be provided.

### BRIEF DESCRIPTION OF THE DRAWINGS

FIG. 1 is a perspective view schematically illustrating a part of a semiconductor device according to an embodiment.

FIG. 2 is a cross-sectional view of a semiconductor device according to an embodiment.

FIG. 3 is a plan view of the semiconductor device according to an embodiment, taken along line A-A′ of FIG. 2.

FIG. 4 and FIG. 5 are plan views of semiconductor devices according to other embodiments, taken along line A-A′ of FIG. 2.

FIG. 6 to FIG. 19 are drawings for explaining a method of manufacturing a semiconductor device according to an embodiment.

FIG. 20 is a cross-sectional view of a semiconductor device according to another embodiment.

FIG. 21 is a plan view of the semiconductor device according to another embodiment, taken along line A-A′ of FIG. 20.

FIG. 22 is a cross-sectional view of a semiconductor device according to another embodiment.

FIG. 23 is a plan view of the semiconductor device according to another embodiment, taken along line A-A′ of FIG. 22.

FIG. 24 to FIG. 33 are drawings for explaining a method of manufacturing a semiconductor device according to another embodiment.

### DETAILED DESCRIPTION OF THE EMBODIMENTS

Hereinafter, various embodiments of the present invention will be described in detail with reference to the attached drawings so that a person having ordinary skill in the art to which the present invention pertains can easily implement the invention. The present invention may be embodied in many different forms and is not limited to the embodiments described herein.

In order to clearly explain the present invention, parts irrelevant to the description are omitted, and the same reference numerals are used for identical or similar components throughout the specification.

In addition, the size and thickness of each component shown in the drawing are arbitrarily shown for convenience of explanation, so the present invention is not necessarily limited to what is shown. In the drawings, the thicknesses of layers, films, panels, regions, etc., are exaggerated for clarity. And in the drawing, for convenience of explanation, the thickness of some layers and areas is exaggerated.

Also, when we say that a part, such as a layer, membrane, region, or plate, is “over” or “on” another part, this includes not only cases where it is “directly over” the other part, but also cases where there are other parts in between. In contrast, when an element is referred to as being “directly on” another element, there are no intervening elements present. Also, being “above” or “on” a reference part means being located above or below the reference part, and does not necessarily mean being located “above” or “on” the opposite direction of gravity.

In addition, unless explicitly described to the contrary, the word “comprise”, and variations such as “comprises” or “comprising”, will be understood to imply the inclusion of stated elements but not the exclusion of any other elements.

Additionally, throughout the specification, when we say “in plan”, we mean when the target portion is viewed from above, and when we say “in cross section”, we mean when the target portion is viewed from the side in a cross-section cut vertically.

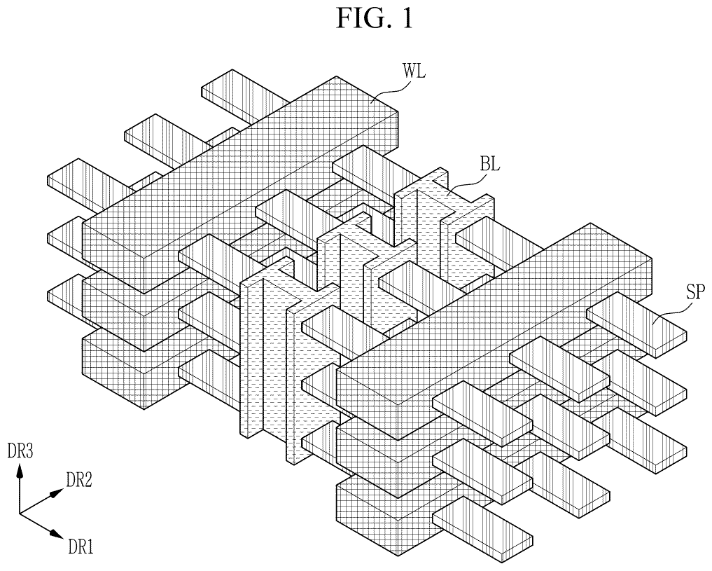

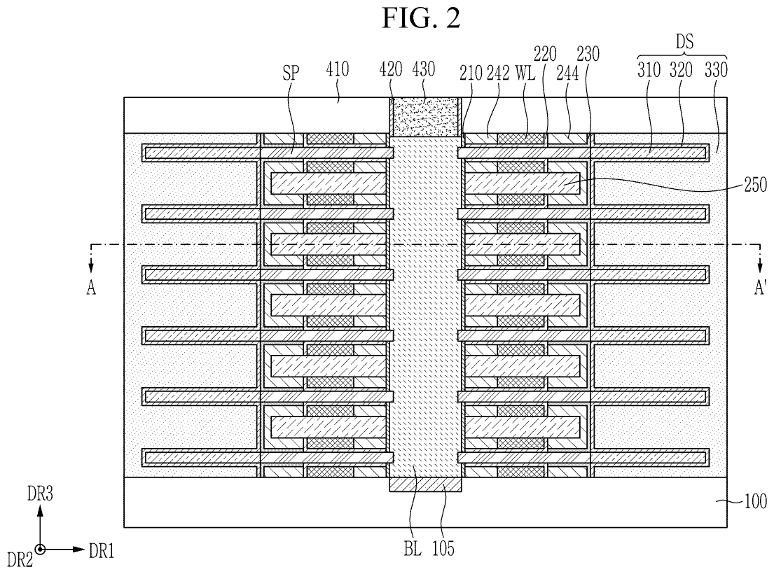

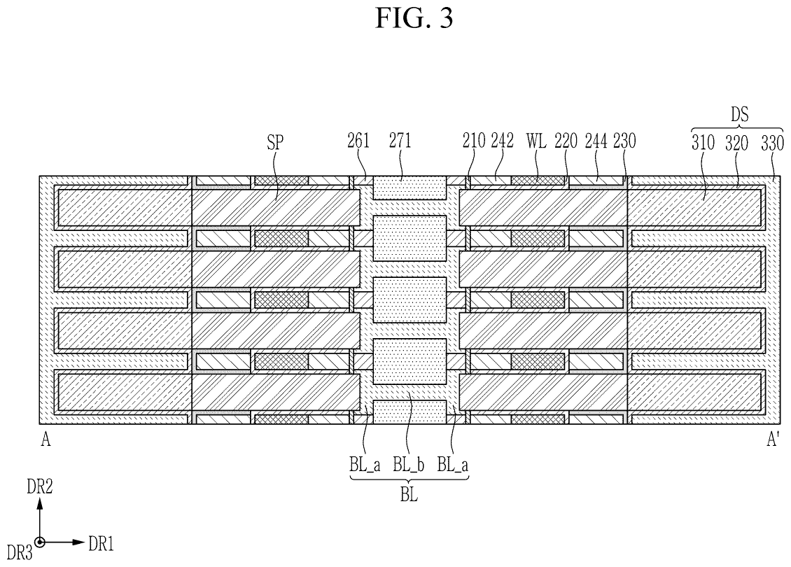

FIG. 1 is a perspective view schematically illustrating a part of a semiconductor device according to an embodiment. FIG. 2 is a cross-sectional view of a semiconductor device according to an embodiment. FIG. 3 is a plan view of the semiconductor device according to an embodiment, taken along line A-A′ of FIG. 2.

Referring to FIG. 1 and FIG. 2, a semiconductor device according to one embodiment may include a substrate 100, a bit line BL, a semiconductor pattern SP, and a word line WL.

For convenience of explanation, only the bit line BL, the word line WL, and the semiconductor pattern SP are illustrated in FIG. 1, and some components included in the semiconductor device are omitted.

The substrate 100 may be, for example, a silicon substrate, a germanium substrate, or a silicon-germanium substrate. The substrate 100 may have a shape extending in a first direction DR1 and a second direction DR2. The second direction DR2 may be a direction intersecting the first direction DR1. For example, the first direction DR1 and the second direction DR2 can be orthogonal to each other. For example, the first direction DR1 and the second direction DR2 may be directions parallel to the upper surface of the substrate 100. Although not shown, additional peripheral circuitry may be provided on the substrate 100.

The bit line BL extending in a third direction DR3 may be positioned on the upper surface of the substrate 100. The bit line BL may have a shape extending in the third direction DR3 that is perpendicular to the upper surface of the substrate 100. The third direction DR3 may be a direction intersecting the first direction DR1 and the second direction DR2. For example, the second direction DR2 and the third direction DR3 can be orthogonal to each other. The third direction DR3 and the first direction DR1 can be orthogonal to each other. For example, the third direction DR3 may be a direction perpendicular to the upper surface of the substrate 100.

A field insulating layer 105 may be positioned on the substrate 100. The field insulating layer 105 may be positioned between the bit line BL and the substrate 100. The field insulating layer 105 may be positioned within the substrate 100. The upper surface of the field insulating layer 105 may be positioned at the same level as the upper surface of the substrate 100, but is not limited thereto. The upper surface of the field insulating layer 105 may be positioned above the upper surface of the substrate 100. For example, the field insulating layer 105 is positioned above the upper surface of the substrate 100. The semiconductor patterns SP may be stacked in the third direction DR3. Some of the semiconductor patterns SP positioned lower in the third direction DR3 may not be connected to the bit line BL due to the field insulating layer 105.

The field insulating layer 105 may have a shape extending in the second direction DR2. The field insulating layer 105 can be connected to the plurality of bit lines BL spaced apart from each other in the second direction DR2. For example, the field insulating layer 105 may be positioned beneath the plurality of bit lines BL.

The field insulating layer 105 can play a role in blocking electrical connection between the substrate 100 and the bit line BL. The field insulating layer 105 may include an insulating material. By way of example, the field insulating layer 105 may include at least one of silicon oxide (SiO), silicon nitride (SiN), and silicon oxynitride (SiON), but is not limited thereto.

The bit line BL may be positioned on the substrate 100. The plurality of bit lines BL can be positioned on the substrate 100. The bit line BL may be positioned on the field insulating layer 105. For example, the plurality of bit lines BL may be positioned on one field insulating layer 105. The plurality of bit lines BL can be positioned spaced apart along the second direction DR2.

The bit line BL can be connected to the semiconductor patterns SP positioned on opposite sides. For example, the bit line BL can be connected to the semiconductor patterns SP positioned on opposite sides in the first direction DR1. The bit line BL can be connected to the semiconductor patterns SP stacked in the third direction DR3.

The bit line BL can be positioned to overlap the semiconductor pattern SP in the first direction DR1. The bit line BL can overlap the end of the semiconductor pattern SP in the second direction DR2. However, this is not limited to this, and in some embodiments, the bit line BL may be positioned so as not to overlap the semiconductor pattern SP in the second direction DR2.

The bit line BL may include a first portion BL_a connected to the semiconductor patterns SP positioned on opposite sides and a second portion BL_b positioned between the first portions BL_a. The bit line BL may include a pair of the first portions BL_a positioned spaced apart in the first direction DR1 and the second portion BL_b positioned between the pair of first portions BL_a. For example, the bit line BL may have an “H” shape in a plan view. For example, the corner portion of the bit line BL may have an angular shape, but is not limited thereto.

The first portion BL_a can be connected to a semiconductor pattern SP. The first portion BL_a can cover one side surface and part of the upper and lower surfaces of the semiconductor pattern SP. The first portion BL_a can contact one side surface and part of the upper and lower surfaces of the semiconductor pattern SP. The first portion BL_a can be connected to the plurality of semiconductor patterns SP stacked in the third direction DR3. For example, one bit line BL may include the pair of first portions BL_a positioned spaced apart in the first direction DR1.

The first portion BL_a may have a shape extending in the third direction DR3. Additionally, by way of example, the first portion BL_a may have a shape extending in the second direction DR2. The first portion BL_a may have a relatively larger width in the second direction DR2 compared to the second portion BL_b. For example, one bit line BL may include the second portion BL_b positioned between the pair of first portions BL_a spaced apart in the first direction DR1.

The first portion BL_a of the bit line BL can be positioned to overlap with the semiconductor pattern SP in the first direction DR1. The first portion BL_a can be positioned to overlap with the semiconductor pattern SP in the second direction DR2. However, this is not limited thereto, and in some embodiments, the first portion BL_a may be positioned so as not to overlap with the semiconductor pattern SP in the second direction DR2. The width of the first portion BL_a in the second direction DR2 may be greater than the width of the semiconductor pattern SP in the second direction DR2. However, this is not limited thereto, and in some embodiments, the width of the first portion BL_a in the second direction DR2 may be equal to or smaller than the width of the semiconductor pattern SP in the second direction DR2.

The second portion BL_b can be positioned between the first portions BL_a. The second portion BL_b can connect the first portions BL_a positioned on opposite sides.

The second portion BL_b may have a shape extending in the third direction DR3. Additionally, by way of example, the second portion BL_b may have a shape extending in the first direction DR1. The second portion BL_b may have a relatively smaller width in the second direction DR2 compared to the first portion BL_a.

The second portion BL_b of the bit line BL can be positioned to overlap the semiconductor pattern SP in the first direction DR1.

The bit line BL may include a conductive material. The first portion BL_a and the second portion BL_b of the bit line BL may include a conductive material. The conductive material can be, for example, one of a doped semiconductor material such as doped silicon (doped Si) or doped germanium (doped Ge), a conductive metal nitride such as titanium nitride (TiN) or tantalum nitride (TaN), a metal such as tungsten (W), titanium (Ti), or tantalum (Ta), or a metal-semiconductor compound such as tungsten silicide (WSiₓ), cobalt silicide (CoSiₓ), or titanium silicide (TiSiₓ).

In FIG. 1, three bit lines BL are positioned on the substrate 100, and in FIG. 2 and FIG. 3, four bit lines BL are positioned on the substrate 100, but the present invention is not limited thereto. The plurality of bit lines BL can be positioned spaced apart from each other in the first direction DR1 and the second direction DR2 on the substrate 100.

The semiconductor pattern SP can be positioned on the substrate 100. The semiconductor pattern SP may have a shape extending in the first direction DR1. For example, the semiconductor pattern SP may have a bar shape extending in the first direction DR1. The semiconductor pattern SP may partially protrude from a second insulating layer 230 toward a data storage element DS.

The semiconductor pattern SP can be connected to the bit line BL. One end of the semiconductor pattern SP can be connected to the bit line BL. The semiconductor pattern SP can be positioned to penetrate a first insulating layer 210. For example, one end of the semiconductor pattern SP may be capped by the bit line BL, but is not limited thereto. For example, one end of a semiconductor pattern SP may be in contact with one end of the bit line BL.

For example, the semiconductor pattern SP may include silicon (Si), germanium (Ge), or silicon-germanium (SiGe). The semiconductor pattern SP may include a channel region, a first impurity region, and a second impurity region.

The first impurity region and the second impurity region may represent regions in which the semiconductor pattern SP is doped with impurities. The first impurity region and the second impurity region can have a conductivity type of n-type or p-type. For example, the first impurity region and the second impurity region may be positioned at each end of the semiconductor pattern SP.

One end of the semiconductor pattern SP can be connected to the bit line BL. The semiconductor pattern SP may be connected to the bit line BL in a form that partially protrudes inside the bit line BL, but is not limited thereto. For example, one side surface of one end of the semiconductor pattern SP may not protrude and may be in contact with the side surface of the bit line BL.

The other end of the semiconductor pattern SP can be connected to the data storage element DS. For example, the first impurity region of the semiconductor pattern SP may be connected to the bit line BL, and the second impurity region of the semiconductor pattern SP may be connected to the data storage element DS. The channel region may be positioned between the first impurity region and the second impurity region.

The plurality of semiconductor patterns SP may be positioned on the substrate 100, and the plurality of semiconductor patterns SP may be stacked so as to be spaced apart from each other along the third direction DR3. For example, the plurality of semiconductor patterns SP connected to one bit line BL can be positioned to be spaced apart from each other along the third direction DR3. Additionally, the plurality of semiconductor patterns SP may be positioned to be spaced apart from each other in the first direction DR1 and the second direction DR2 along the bit lines BL that are positioned to be spaced apart from each other in the first direction DR1 and the second direction DR2.

The word line WL can be positioned on the semiconductor pattern SP. The word line WL may have a shape extending along the second direction DR2. For example, the word line WL may have a bar shape extending along the second direction.

For example, one word line WL may be positioned to surround a portion of the semiconductor pattern SP. The word line WL can cover the center area of the semiconductor pattern SP. The word line WL can cover the channel region positioned between the first impurity region and the second impurity region of the semiconductor pattern SP. The word line WL may have a form extending in the second direction DR2, and the semiconductor pattern SP may be positioned in a form penetrating the word line WL in the first direction DR1. In some embodiments, the pair of word lines may be respectively positioned above and below the semiconductor pattern SP. The plurality of word lines WL may be positioned on the substrate 100, and the plurality of word lines WL may be stacked while being spaced apart from each other in the third direction DR3.

The word line WL may include a conductive material. The conductive material can be any one of a semiconductor material, a conductive metal nitride, a metal, or a metal-semiconductor compound.

The semiconductor device according to one embodiment may further include a first insulating layer 210, a gate insulating pattern 220, a second insulating layer 230, a first spacer 242, a second spacer 244, and an interlayer insulating layer 250.

The first insulating layer 210 may be placed on one side surface of the bit line BL. The first insulating layer 210 may be positioned between the bit line BL and the first spacer 242. Additionally, the first insulating layer 210 may be positioned between the bit line BL and the interlayer insulating layer 250.

The gate insulating pattern 220 may be placed between the word line WL and the semiconductor pattern SP. The semiconductor pattern SP and the word line WL can be positioned to be spaced apart in the third direction DR3 with the gate insulating pattern 220 interposed therebetween. The gate insulating pattern 220 may be further positioned between the first spacer 242 and the semiconductor pattern SP. Additionally, by way of example, the gate insulating pattern 220 may be further positioned between the word line WL and the second spacer 244. For example, the gate insulating pattern 220 may have an “L” shape in the cross-section in the first direction DR1 and the third direction DR3, but is not limited thereto. For example, the gate insulating pattern 220 may have a straight line shape extending along the semiconductor pattern SP in the cross-section in the first direction DR1 and the third direction DR3.

The gate insulating pattern 220 may include an insulating material. The gate insulating pattern 220 may include a silicon oxide film, a silicon oxynitride film, a high-k film having a higher dielectric constant than the silicon oxide film, or a combination thereof. The high-k dielectric film can be made of a metal oxide or a metal oxide nitride. For example, the high-k dielectric film that can be used as the gate insulating pattern 220 may include, but is not limited to, hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), zirconium oxide (ZrO₂), aluminum oxide (Al₂O₃), or a combination thereof.

The second insulating layer 230 may be positioned between the second spacer 244 and the semiconductor pattern SP. The second insulating layer 230 may be positioned between the second spacer 244 and the data storage element DS. For example, the second insulating layer 230 may have an “L” shape in the cross-section in the first direction DR1 and the third direction DR3, but is not limited thereto.

The first spacer 242 may be positioned between the word line WL and the bit line BL. The first spacer 242 may have a shape that surrounds a portion of the semiconductor pattern SP between the word line WL and the bit line BL. The first spacer 242 may be positioned between the first insulating layer 210 and the word line WL.

The second spacer 244 may be positioned between the word line WL and the data storage element DS. The first spacer 242 and the second spacer 244 can be positioned on opposite sides of the word line WL. The second spacer 244 may have a form that surrounds a portion of the semiconductor pattern SP between the word line WL and the data storage element DS. The second spacer 244 may be positioned between the second insulating layer 230 and the interlayer insulating layer 250.

The first insulating layer 210, the second insulating layer 230, the first spacer 242, and the second spacer 244 may include an insulating material. The first insulating layer 210, the second insulating layer 230, the first spacer 242, and the second spacer 244 may include the same insulating material. Alternatively, at least one of the first insulating layer 210, the second insulating layer 230, the first spacer 242, and the second spacer 244 may include different insulating materials. For example, the first insulating layer 210, the second insulating layer 230, the first spacer 242, and the second spacer 244 may include at least one of silicon oxide (SiO), silicon nitride (SiN), or silicon oxynitride (SiON), but are not limited to. The first insulating layer 210, the second insulating layer 230, the first spacer 242, and the second spacer 244 may be formed simultaneously or may be formed separately.

The interlayer insulating layer 250 may be placed between the plurality of semiconductor patterns SP. The plurality of semiconductor patterns SP may be positioned to be spaced apart in the third direction DR3, and the interlayer insulating layer 250 may be positioned between the plurality of semiconductor patterns SP spaced apart in the third direction DR3.

The interlayer insulating layer 250 may be positioned over the word line WL. The interlayer insulating layer 250 may be positioned over the first spacer 242. Additionally, the interlayer insulating layer 250 may be positioned between the plurality of word lines WL. The plurality of word lines WL may be positioned to be spaced apart in the third direction DR3, and the interlayer insulating layer 250 may be positioned between the plurality of word lines WL spaced apart in the third direction DR3. The interlayer insulating layer 250 may be positioned between the second spacer 244 and the bit line BL. The interlayer insulating layer 250 may be positioned between the second spacer 244 and the first insulating layer 210. For example, one side surface of the interlayer insulating layer 250 may be in contact with the first insulating layer 210, and the other side surface of the interlayer insulating layer 250 may be in contact with the second spacer 244.

The interlayer insulating layer 250 may include an insulating material. By way of example, the interlayer insulating layer 250 may include, but is not limited to, at least one of silicon oxide (SiO), silicon nitride (SiN), and silicon oxynitride (SiON).

The semiconductor device according to one embodiment may include the data storage element DS.

The data storage element DS can be connected to the semiconductor pattern SP. The other end of the semiconductor pattern SP can be connected to the data storage element DS. The plurality of data storage elements DS can be positioned to be stacked in the third direction DR3.

The data storage element DS may include a first electrode 310, a dielectric layer 320, and a second electrode 330.

The first electrode 310 can be connected to the other end of the semiconductor pattern SP. One end of the first electrode 310 can be connected to the semiconductor pattern SP. The first electrode 310 can cover a portion of the other side surface and upper and lower surfaces of the semiconductor pattern SP. The first electrode 310 may have a shape surrounding the other end of the semiconductor pattern SP. The first electrode 310 may be positioned at substantially the same level as the semiconductor pattern SP. The first electrode 310 can be aligned parallel to the semiconductor pattern SP in the first direction DR1.

The first electrode 310 may have a shape extending in the first direction DR1. The first electrode 310 may have a bar or pillar shape extending in the first direction DR1, but is not limited thereto. For example, the first electrode 310 may have a cylinder shape with a hollow center. The width of the first electrode 310 in the second direction DR2 and/or the third direction DR3 may be substantially the same as the width of the semiconductor pattern SP in the second direction DR2 and/or the third direction DR3, but is not limited thereto. For example, the width of the first electrode 310 in the second direction DR2 and/or the third direction DR3 may be different from the width of the semiconductor pattern SP in the second direction DR2 and/or the third direction DR3.

The dielectric layer 320 may be positioned on the first electrode 310. The dielectric layer 320 may be positioned between the first electrode 310 and the second electrode 330. The dielectric layer 320 can cover the upper, lower, and side surfaces of the first electrode 310. For example, the side surface of the first electrode 310 may mean a surface that is perpendicular to the upper surface of the substrate 100. Additionally, the dielectric layer 320 may cover a portion of the other side surface of the first electrode 310. The other side surface of the first electrode 310 may mean a surface opposite to one side surface of the first electrode 310 where the first electrode 310 and the semiconductor pattern SP are connected. The other side surface of the first electrode 310 may be covered by the dielectric layer 320. The dielectric layer 320 can be conformally placed on the first electrode 310. The dielectric layer 320 can be placed on the second insulating layer 230. The first spacer 242 and the second spacer 244 may be placed on the interlayer insulating layer 250, the second insulating layer 230 may be placed on the second spacer 244, and the dielectric layer 320 may be placed on the second insulating layer 230. For example, the second spacer 244 may be placed on a side surface of the interlayer insulating layer 250.

The dielectric layer 320 may include an insulating material. The dielectric layer 320 may include a silicon oxide film, a silicon oxynitride film, a high-k dielectric film having a higher dielectric constant than the silicon oxide film, or a combination thereof. The high-k dielectric film can be made of a metal oxide or a metal oxide nitride. For example, the high-k dielectric films usable as the dielectric layer 320 may include hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), zirconium oxide (ZrO₂), aluminum oxide (Al₂O₃), or combinations thereof, but are not limited to.

The second electrode 330 may be positioned on the dielectric layer 320. The second electrode 330 can fill the space between the plurality of first electrodes 310. The data storage elements DS of multiple layers stacked in the third direction DR3 can share one second electrode 330.

The second electrode 330 may include a conductive material. The second electrode 330 may include, for example, at least one of a metal material such as titanium (Ti), tantalum (Ta), tungsten (W), copper (Cu), aluminum (Al), platinum (Pt), iridium (Ir), or ruthenium (Ru), a conductive metal nitride such as titanium nitride (TiN), molybdenum nitride (MoN), vanadium nitride (VN), niobium nitride (NbN), or tantalum nitride (TaN), a conductive metal oxide such as ruthenium oxide (RuOₓ), iridium oxide (IrO), indium tin oxide (ITO), molybdenum oxide (MoOₓ), and vanadium oxide (VOₓ), or a doped semiconductor material such as doped silicon (doped Si) or doped germanium (doped Ge).

The semiconductor device according to one embodiment may include a first intermediate insulating pattern 261, a second intermediate insulating pattern 271, a protective layer 410, a pad spacer 420, and a pad electrode 430.

The first intermediate insulating pattern 261 may be positioned between the plurality of bit lines BL. The first intermediate insulating pattern 261 can be positioned between the plurality of bit lines BL in the second direction DR2. The first intermediate insulating pattern 261 can be positioned on opposite sides of the second intermediate insulating pattern 271 in the first direction DR1. The pair of first intermediate insulating patterns 261 can be positioned on opposite sides of the second intermediate insulating pattern 271 in the first direction DR1. The first intermediate insulating pattern 261 can be in contact with the other end of the semiconductor pattern SP. The first intermediate insulating pattern 261 can be in contact with the bit line BL. The first intermediate insulating pattern 261 can be in contact with the first portion BL_a of the bit line BL. The first intermediate insulating pattern 261 may be positioned so as not to overlap the bit line BL in the first direction DR1, but is not limited thereto. The first intermediate insulating pattern 261 can be positioned to overlap the bit line BL in the second direction DR2. The first intermediate insulating pattern 261 can be positioned to overlap the first portion BL_a in the second direction DR2. The first intermediate insulating pattern 261 can be positioned to overlap with an end of the semiconductor pattern SP in the second direction DR2. The first intermediate insulating pattern 261 can be positioned on opposite sides of the first portion BL_a in the second direction DR2. The first intermediate insulating pattern 261 may be positioned between the plurality of first portions BL_a.

The first intermediate insulating pattern 261 may have a form extending in the third direction DR3 along the bit line BL. The width of the first intermediate insulating pattern 261 in the second direction DR2 may be greater than the width of the second intermediate insulating pattern 271 in the second direction DR2. The width of the first intermediate insulating pattern 261 in the first direction DR1 may be smaller than the width of the second intermediate insulating pattern 271 in the first direction DR1, but is not limited thereto.

The second intermediate insulating pattern 271 may be positioned between the plurality of bit lines BL. The second intermediate insulating pattern 271 can be positioned between the plurality of bit lines BL in the second direction DR2. The second intermediate insulating pattern 271 can be positioned between the first intermediate insulating patterns 261. The second intermediate insulating pattern 271 can be positioned between the pair of first intermediate insulating patterns 261 in the first direction DR1. The second intermediate insulating pattern 271 can be in contact with the bit line BL. The second intermediate insulating pattern 271 can be in contact with the second portion BL_b of the bit line BL. The second intermediate insulating pattern 271 can be positioned to overlap the second portion BL_b in the second direction DR2. The second intermediate insulating pattern 271 can be positioned to overlap the bit line BL in the first direction DR1. The second intermediate insulating pattern 271 can be positioned to overlap the first portion BL_a in the first direction DR1. The second intermediate insulating pattern 271 can be positioned on opposite sides of the second portion BL_b in the second direction DR2. The second intermediate insulating pattern 271 may be positioned between the plurality of second portions BL_b.

The second intermediate insulating pattern 271 may have a form extending in the third direction DR3 along the bit line BL. The width of the second intermediate insulating pattern 271 in the second direction DR2 may be smaller than the width of the first intermediate insulating pattern 261 in the second direction DR2. The width of the second intermediate insulating pattern 271 in the first direction DR1 may be greater than the width of the first intermediate insulating pattern 261 in the first direction DR1, but is not limited thereto.

The first intermediate insulating pattern 261 and the second intermediate insulating pattern 271 may include an insulating material. For example, the first intermediate insulating pattern 261 and the second intermediate insulating pattern 271 may include at least one of silicon oxide (SiO), silicon nitride (SiN), and silicon oxynitride (SiON), but are not limited to.

The first intermediate insulating pattern 261 and the second intermediate insulating pattern 271 may include the same insulating material, but are not limited thereto, and may include different insulating materials. The first intermediate insulating pattern 261 and the second intermediate insulating pattern 271 may have different etching ratios. The first intermediate insulating pattern 261 and the second intermediate insulating pattern 271 may have different etching ratios under the same conditions. For example, the first intermediate insulating pattern 261 and the second intermediate insulating pattern 271 may have differences in etching ratios depending on conditions such as the formation method, formation temperature, post-heat treatment method, and post-heat treatment temperature.

The first intermediate insulating pattern 261 and the second intermediate insulating pattern 271 may have different composition ratios. The first intermediate insulating pattern 261 and the second intermediate insulating pattern 271 may include the same material, but the composition ratio of the material may be different. The first intermediate insulating pattern 261 and the second intermediate insulating pattern 271 may exhibit differences in etching ratios due to differences in composition ratios. The first intermediate insulating pattern 261 can have a higher etching ratio than the second intermediate insulating pattern 271. The first intermediate insulating pattern 261 can have a higher etching ratio under the same conditions compared to the second intermediate insulating pattern 271. For example, the first intermediate insulating pattern 261 and the second intermediate insulating pattern 271 may include silicon oxide (SiOₓ) having different etching ratios. Additionally, the first intermediate insulating pattern 261 and the second intermediate insulating pattern 271 may have different composition ratios of silicon (Si) and oxygen (O) in silicon oxide (SiOₓ). However, without limitation thereto, for example, when the first intermediate insulating pattern 261 and the second intermediate insulating pattern 271 are a mixture of multiple insulating materials, a difference in the etching ratio may appear depending on the content ratio of the insulating materials.

The protective layer 410 may be positioned on top of the plurality of semiconductor patterns SP stacked in the third direction DR3. The protective layer 410 may be positioned on top of the plurality of word lines WL stacked in the third direction DR3. The protective layer 410 may be positioned on top of the data storage elements DS stacked in the third direction DR3. For example, the protective layer 410 may be positioned at the top layer of the semiconductor device.

The protective layer 410 may have a form extending in the first direction DR1 and the second direction DR2.

The protective layer 410 can play a role in protecting the semiconductor pattern SP, word line WL, and data storage element DS. By way of example, the protective layer 410 may include silicon (Si), but is not limited to. For example, the protective layer 410 may include an insulating material such as silicon oxide (SiOₓ), silicon nitride (SiN), etc.

The pad spacer 420 may be positioned above the bit line BL. The pad spacer 420 may be positioned between the protective layer 410 and the pad electrode 430.

The pad spacer 420 can be positioned on opposite sides of the pad electrode 430. The pad spacer 420 may have a shape that surrounds the side wall of the pad electrode 430.

The pad spacer 420 may include an insulating material. For example, the pad spacer 420 may include at least one of silicon oxide (SiO), silicon nitride (SiN), and silicon oxynitride (SiON), but is not limited to.

The pad electrode 430 may be positioned above the bit line BL. The pad electrode 430 can be connected to the bit line BL. The pad electrode 430 can be positioned to penetrate the protective layer 410.

The pad electrode 430 may have a shape substantially identical to that of the bit line BL in a plan view. For example, the bit line BL may have an “H” shape in a plan view, and the pad electrode 430 may have an “H” shape in a plan view, but is not limited thereto. For example, the pad electrode 430 may have a polygonal shape in a plan view such as a circle, an oval, a rectangle, etc., and may be variously changed as needed.

The pad electrode 430 may include a conductive material. For example, the pad electrode 430 may include at least one of a metal material such as titanium (Ti), tantalum (Ta), tungsten (W), copper (Cu), aluminum (Al), platinum (Pt), iridium (Ir), or ruthenium (Ru), a conductive metal nitride such as titanium nitride (TiN), molybdenum nitride (MoN), vanadium nitride (VN), niobium nitride (NbN), or tantalum nitride (TaN), a conductive metal oxide such as ruthenium oxide (RuOₓ), iridium oxide (IrO), indium tin oxide (ITO), molybdenum oxide (MoOₓ), and vanadium oxide (VOₓ), or a doped semiconductor material such as doped silicon (doped Si) or doped germanium (doped Ge).

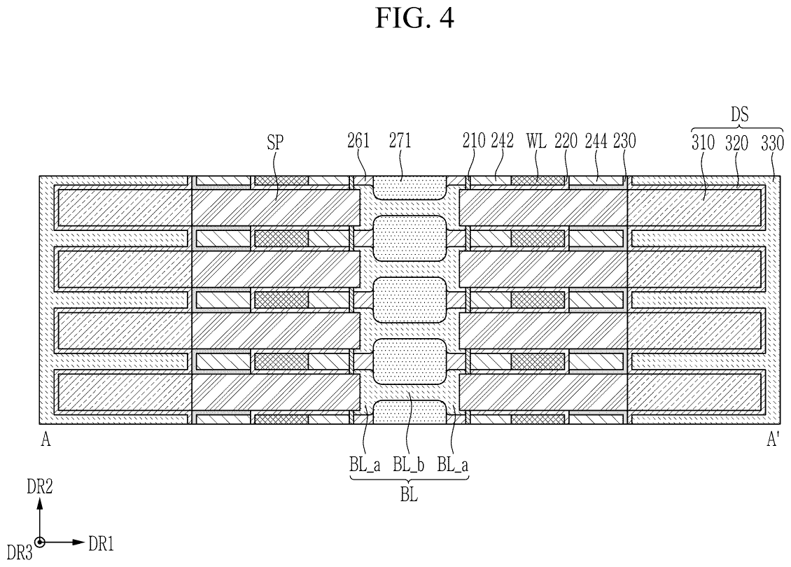

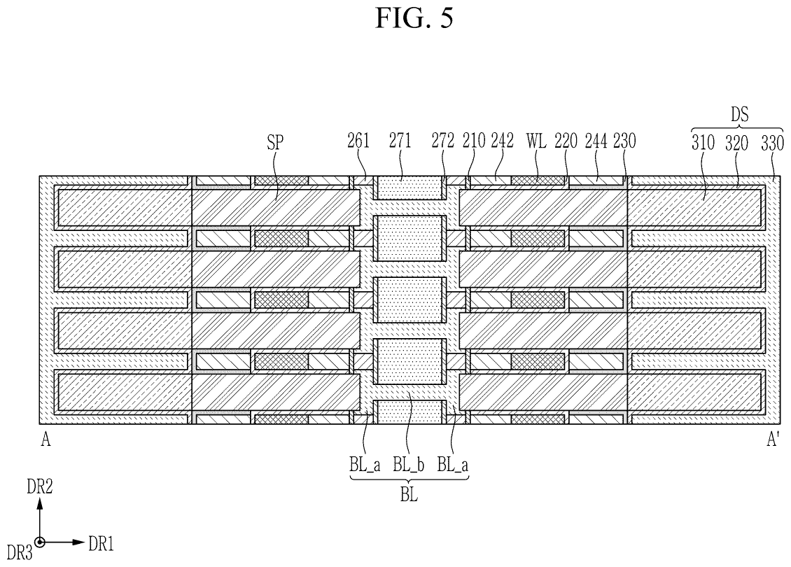

FIG. 4 and FIG. 5 are plan views of semiconductor devices according to other embodiments, taken along line A-A′ of FIG. 2.

Descriptions of parts that are substantially the same as the previous example will be omitted, and explanations will be focused on the differences.

Referring to FIG. 4, the semiconductor device may include the bit line BL including the first portion BL_a and the second portion BL_b. The corners of the bit line BL may have a rounded shape rather than an angular shape. The corner of the first portion BL_a and the second portion BL_b of the bit line BL may have a rounded shape. Accordingly, the corner of the first intermediate insulating pattern 261 and the second intermediate insulating pattern 261 in contact with the bit line BL may also have a rounded shape.

Referring to FIG. 5, the semiconductor device may further include the first intermediate insulating pattern 261 in contact with the first portion BL_a of the bit line BL, the second intermediate insulating pattern 271 in contact with the second portion BL_b, and a third intermediate insulating pattern 272 positioned between the first intermediate insulating pattern 261 and the second intermediate insulating pattern 271.

The third intermediate insulating pattern 272 may be in contact with a portion of the bit line BL. The third intermediate insulating pattern 272 can be positioned on opposite sides of the second intermediate insulating pattern 271 in the first direction DR1. The third intermediate insulating pattern 272 can be in contact with the first portion BL_a and the second portion BL_b of the bit line BL simultaneously. The third intermediate insulating pattern 272 may have a form extending in the third direction DR3.

The third intermediate insulating pattern 272 may include an insulating material. By way of example, the third intermediate insulating pattern 272 may include at least one of silicon oxide (SiO), silicon nitride (SiN), and silicon oxynitride (SiON), but is not limited to.

The third intermediate insulating pattern 272 may include the same insulating material as the first intermediate insulating pattern 261 and the second intermediate insulating pattern 271, but is not limited thereto and may include a different insulating material. The third intermediate insulating pattern 272 may have an etching ratio different from that of the first intermediate insulating pattern 261 and the second intermediate insulating pattern 271.

For example, the third intermediate insulating pattern 272 can serve as an etching stop film.

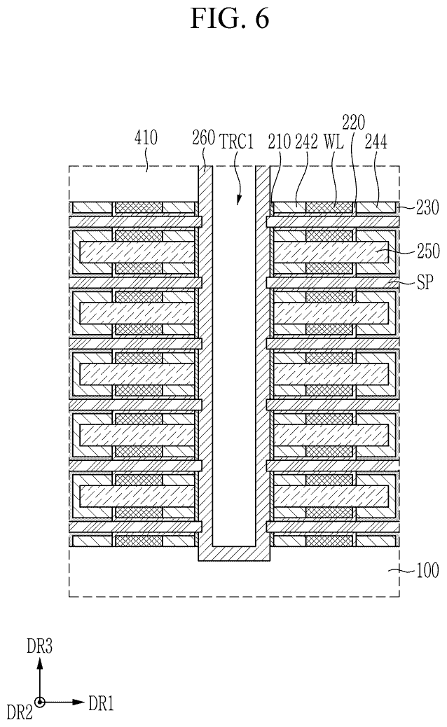

FIG. 6 to FIG. 19 are drawings for explaining a method of manufacturing a semiconductor device according to an embodiment.

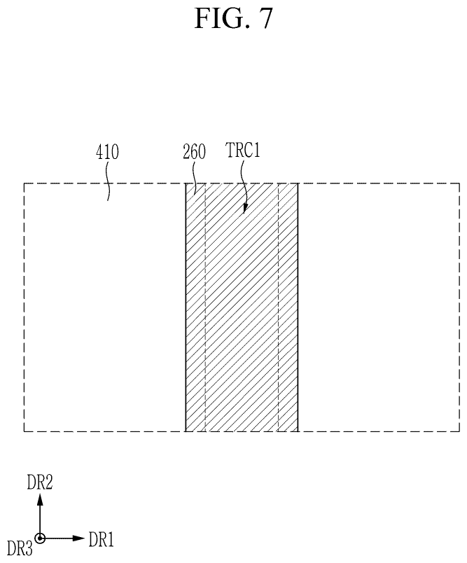

Referring to FIG. 6 and FIG. 7, a first trench TRC1 can be formed between the semiconductor patterns SP spaced apart from each other in the first direction DR1 and stacked in the third direction DR3. The first trench TRC1 may be positioned between interlayer insulating layers 250 spaced apart from each other in the first direction DR1. The first trench TRC1 may be positioned between word lines WL that are spaced apart from each other in the first direction DR1. The first trench TRC1 may be positioned on the substrate 100.

The bottom surface of the first trench TRC1 may be positioned below the upper surface of the substrate 100. For example, the first trench TRC1 may be formed by removing a portion of the substrate 100. The semiconductor patterns SP may partially protrude from the first insulating layer 210 toward the first trench TRC1. The first trench TRC1 may have a shape extending in the second direction DR2 and the third direction DR3.

A first intermediate insulating layer 260 can be formed within the first trench TRC1. The first intermediate insulating layer 260 can be formed on the first insulating layer 210. The first intermediate insulating layer 260 can be formed on the substrate 100. The first intermediate insulating layer 260 can cover an end of the semiconductor pattern SP. The first intermediate insulating layer 260 can be formed on the side surface of the protective layer 410.

The first intermediate insulating layer 260 may include an insulating material. By way of example, the first intermediate insulating layer 260 may include at least one of silicon oxide (SiO), silicon nitride (SiN), and silicon oxynitride (SiON), but is not limited to.

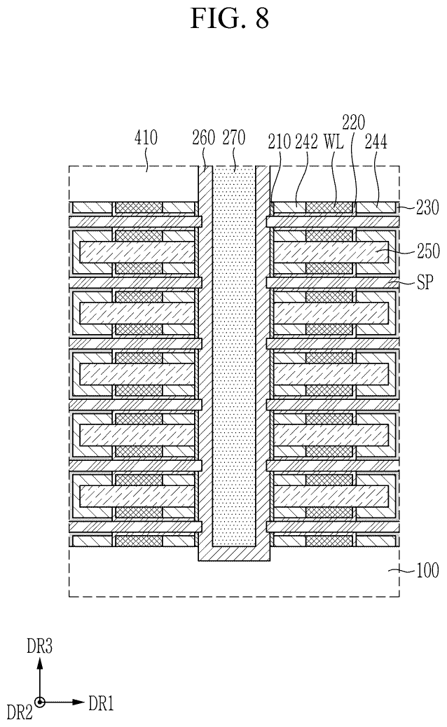

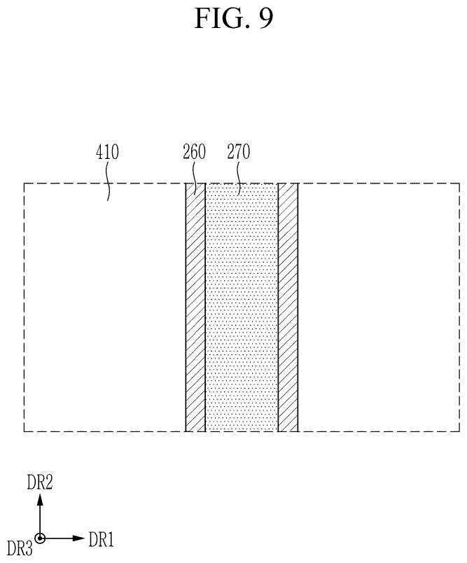

Next, referring to FIG. 8 and FIG. 9, a second intermediate insulating layer 270 can be formed on the first intermediate insulating layer 260. The second intermediate insulating layer 270 may be positioned within the first trench TRC1. The second intermediate insulating layer 270 can fill the first trench TRC1.

The second intermediate insulating layer 270 may not be in contact with the semiconductor pattern SP. The second intermediate insulating layer 270 can be formed spaced apart from the semiconductor pattern SP with the first intermediate insulating layer 260 interposed therebetween.

The second intermediate insulating layer 270 may include an insulating material. By way of example, the second intermediate insulating layer 270 may include at least one of silicon oxide (SiO), silicon nitride (SiN), and silicon oxynitride (SiON), but is not limited to.

The first intermediate insulating layer 260 and the second intermediate insulating layer 270 may include the same insulating material, but are not limited thereto, and may include different insulating materials. The first intermediate insulating layer 260 and the second intermediate insulating layer 270 may have different etching ratios. The first intermediate insulating layer 260 and the second intermediate insulating layer 270 may have different composition ratios. The first intermediate insulating layer 260 and the second intermediate insulating layer 270 may have different etching ratios due to different composition ratios. The first intermediate insulating layer 260 may have a higher etching ratio than the second intermediate insulating layer 270. For example, the first intermediate insulating layer 260 and the second intermediate insulating layer 270 may include silicon oxide (SiO) having different etching ratios. For example, the first intermediate insulating layer 260 and the second intermediate insulating layer 270 may have different etching ratios even if they contain the same insulating material due to differences in formation process conditions, etc. For example, the first intermediate insulating layer 260 and the second intermediate insulating layer 270 may include silicon oxide (SiO), and the first intermediate insulating layer 260 and the second intermediate insulating layer 270 may have different composition ratios of silicon (Si) and oxygen (O).

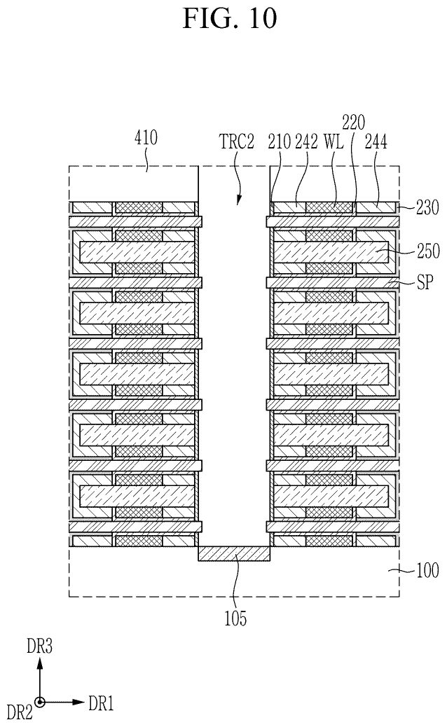

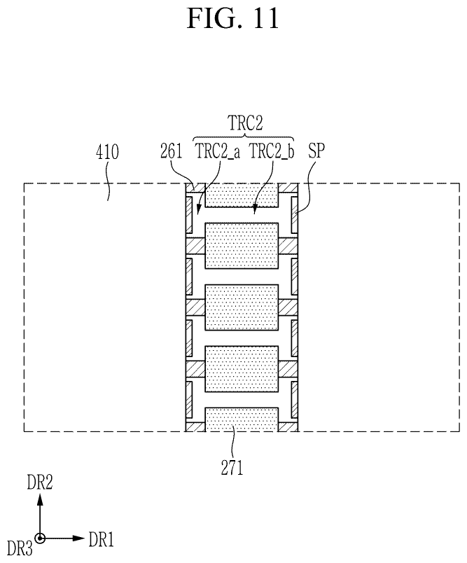

Next, referring to FIG. 10 and FIG. 11, patterning of the first intermediate insulating layer 260 and the second intermediate insulating layer 270 can be performed.

Patterning of the first intermediate insulating layer 260 can be performed in such a way that a portion of the first intermediate insulating layer 260 is removed. The field insulating layer 105 and the first intermediate insulating pattern 261 can be formed through patterning of the first intermediate insulating layer 260. The second intermediate insulating pattern 271 can be formed by patterning the second intermediate insulating layer 270. A second trench TRC2 can be formed by patterning the first intermediate insulating layer 260 and the second intermediate insulating layer 270.

The second trench TRC2 may include a first region TRC2_a and a second region TRC2_b.

The first region TRC2_a can be positioned on opposite sides of the second trench TRC2. The first region TRC2_a may be positioned between the first intermediate insulating patterns 261. The first region TRC2_a can be formed to overlap the first intermediate insulating pattern 261 in the second direction DR2. The other end of the semiconductor pattern SP can be exposed by the first region TRC2_a. The width of the first region TRC2_a in the second direction DR2 may be greater than the width of the second region TRC2_b in the second direction DR2.

The first region TRC2_a can be positioned to overlap with the semiconductor pattern SP in the second direction DR2. However, this is not limited thereto, and in some embodiments, the first region TRC2_a may be positioned so as not to overlap with the semiconductor pattern SP in the second direction DR2. The width of the first region TRC2_a in the second direction DR2 may be greater than the width of the semiconductor pattern SP in the second direction DR2. However, this is not limited thereto, and in some embodiments, the width of the first region TRC2_a in the second direction DR2 may be equal to or smaller than the width of the semiconductor pattern SP in the second direction DR2.

The second region TRC2_b can be positioned between the first regions TRC2_a. The second region TRC2_b may be positioned between the second intermediate insulating patterns 271. The second region TRC2_b can be formed to overlap the second intermediate insulating pattern 271 in the second direction DR2. The width of the second region TRC2_b in the second direction DR2 may be smaller than the width of the first region TRC2_a in the second direction DR2.

The first region TRC2_a and the second region TRC2_b may have a form extending in the third direction DR3.

The second trench TRC2 may have an “H” shape in a plan view, but is not limited thereto. For example, the second trench TRC2 may have a shape such as a “T” shape, a circle, an oval, a square, or a polygon in a plan view.

The field insulating layer 105 may be positioned on the bottom surface of the second trench TRC2. The field insulating layer 105 may be positioned on the substrate 100. The field insulating layer 105 may have a form extending in the second direction DR2 along the first trench TRC1. The first intermediate insulating pattern 261 may be positioned on the substrate 100. The first intermediate insulating pattern 261 may be positioned on the field insulating layer 105. The first intermediate insulating pattern 261 may have a form extending in the third direction DR3. The second intermediate insulating pattern 271 may be positioned on the substrate 100. The second intermediate insulating pattern 271 may be positioned on the field insulating layer 105. The second intermediate insulating pattern 271 may have a form extending in the third direction DR3.

For example, the upper surfaces of the first intermediate insulating pattern 261 and the second intermediate insulating pattern 271 may be positioned at the same level as the upper surface of the protective layer 410.

The first intermediate insulating patterns 261 can be positioned to be spaced apart in the second direction DR2 by the second trench TRC2. The second trench TRC2 may be positioned between the first intermediate insulating patterns 261 in the second direction DR2

The end of the semiconductor pattern SP can be exposed by the second trench TRC2.

No additional mask may be used to form the second trench TRC2. For example, the difference in the width of the first region TRC2_a and the second region TRC2_b of the second trench TRC2 in the second direction DR2 may be caused by a difference in the etching ratio of the first intermediate insulating layer 260 and the second intermediate insulating layer 270. However, without limitation thereto, for example, a photoresist material and an additional mask may be used for patterning the first intermediate insulating layer 260 and the second intermediate insulating layer 270. The photoresist layer and the additional mask can be used to form the second trench TRC2.

A wet etching process may be used for patterning the first intermediate insulating layer 260 and the second intermediate insulating layer 270, but is not limited thereto.

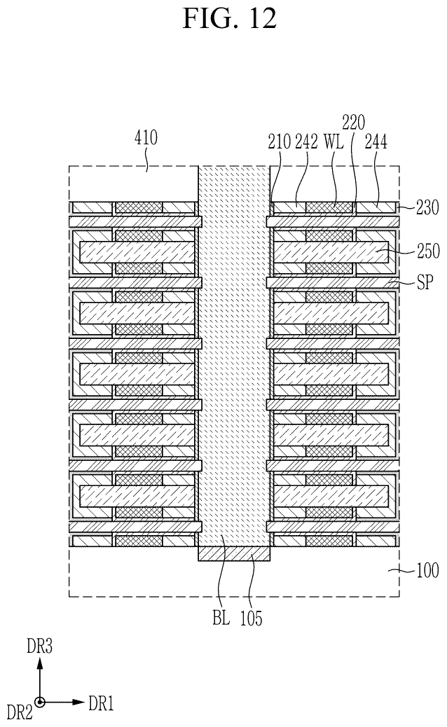

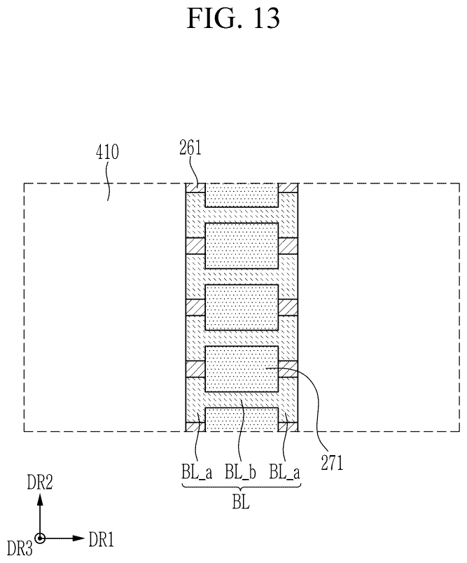

Next, referring to FIG. 12 and FIG. 13, the bit line BL can be formed within the second trench TRC2. The bit line BL may have a shape corresponding to the shape of the second trench TRC2. The bit line BL can have an “H” shape in a plan view.

The bit line BL may include the first portion BL_a and the second portion BL_b. The first portion BL_a can cover an end of the semiconductor pattern SP. The first portion BL_a may be positioned between the first intermediate insulating patterns 261. For example, the first portion BL_a may be formed to overlap with the semiconductor pattern SP in the first direction DR1 and the third direction DR3, but may be formed to not overlap with the semiconductor pattern SP in the second direction DR2.

The second portion BL_b can be positioned between the first portions BL_a positioned on opposite sides. The second portion BL_b may be positioned between the second intermediate insulating patterns 271.

The first portion BL_a and the second portion BL_b may have a shape extending in the third direction DR3. The width of the first portion BL_a in the second direction DR2 may be greater than the width of the second portion BL_b in the second direction DR2.

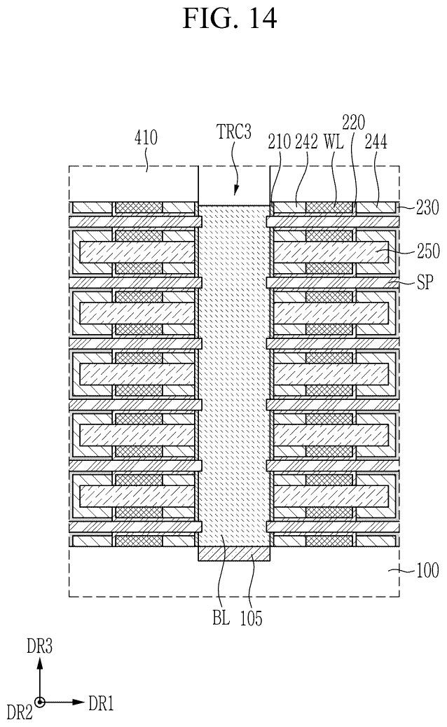

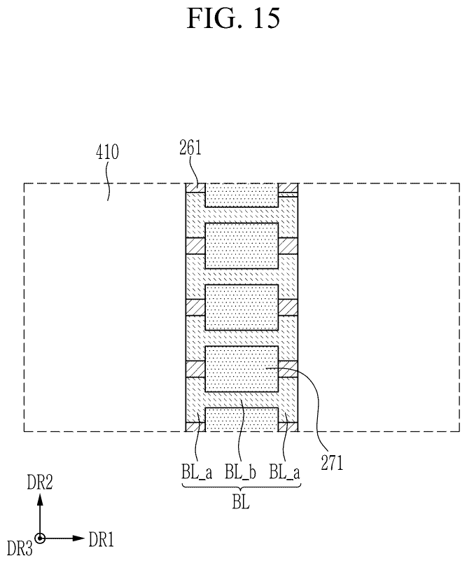

Next, referring to FIG. 14 and FIG. 15, a portion positioned on the upper part of the bit line BL can be removed. The portion positioned on the upper part of the bit line BL may be removed to form a third trench TRC3.

The third trench TRC3 can be formed on the bit line BL. The protective layer 410 may be positioned on opposite sides of the third trench TRC3. The third trench TRC3 may be positioned between the plurality of first intermediate insulating patterns 261 and the plurality of second intermediate insulating patterns 271.

The upper surfaces of the first intermediate insulating pattern 261 and the second intermediate insulating pattern 271 may be positioned at substantially the same level as the upper surface of the protective layer 410. The planar shape of the third trench TRC3 may be substantially identical to the planar shape of the bit line BL. The third trench TRC3 can be formed using the first intermediate insulating pattern 261, the second intermediate insulating pattern 271, and the protective layer 410 as masks, and can be formed without using an additional mask.

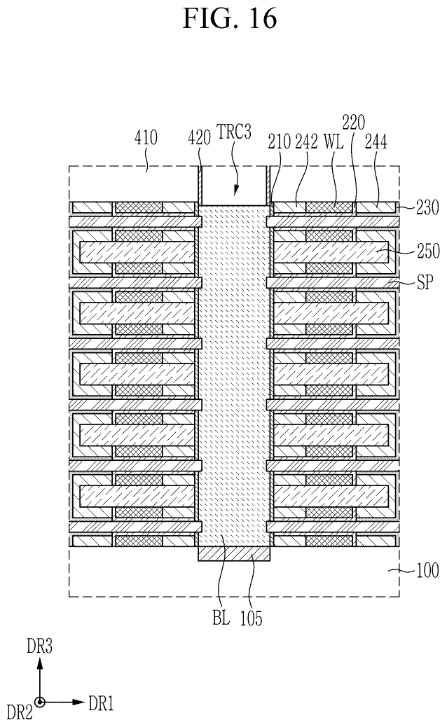

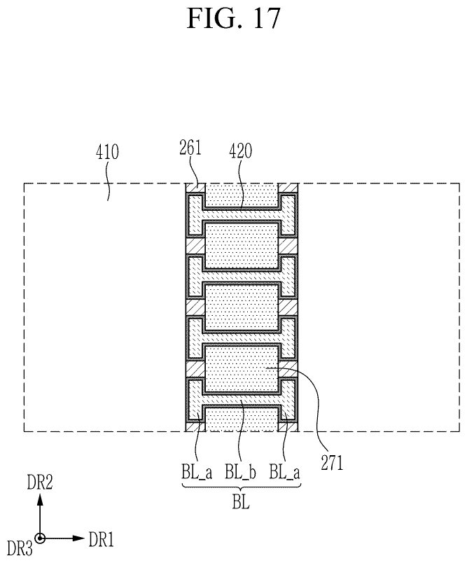

Next, referring to FIG. 16 and FIG. 17, the pad spacer 420 may be formed within the third trench TRC3. The pad spacer 420 may be positioned on the bit line BL. The pad spacer 420 can be formed in a shape that surrounds the side wall of the third trench TRC3. The pad spacer 420 can be conformally formed along the side wall of the third trench TRC3.

For example, the pad spacer 420 may be formed by depositing an insulating material within the third trench TRC3 and then removing a portion positioned on the bottom surface, but is not limited thereto.

The process of forming the pad spacer 420 can use the first intermediate insulating pattern 261, the second intermediate insulating pattern 271, and the protective layer 410 formed in the previous process as masks.

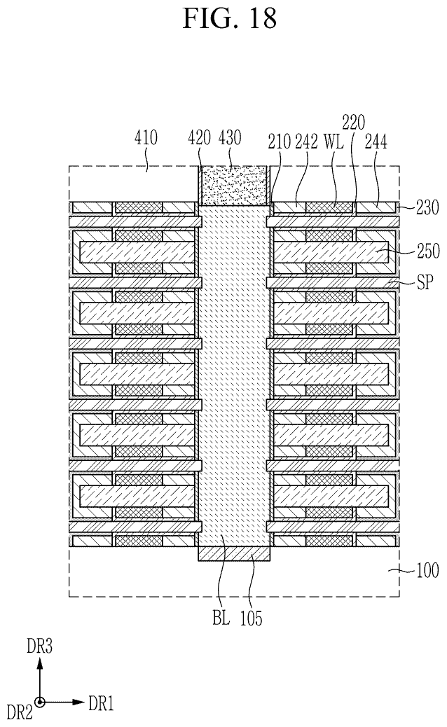

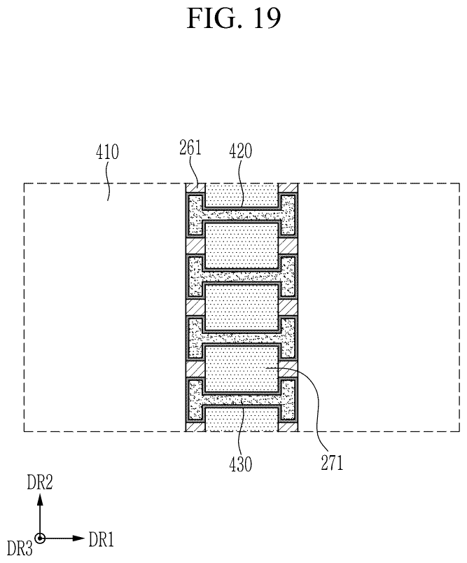

Next, referring to FIG. 18 and FIG. 19, the pad electrode 430 can be filled within the third trench TRC3. The pad electrode 430 may be positioned on the bit line BL. The pad electrode 430 can be electrically connected to the bit line BL. The pad electrode 430 may have a planar shape substantially identical to the planar shape of the bit line BL. The pad spacer 420 may be positioned between the pad electrode 430 and the protective layer 410.

The process of forming the pad electrode 430 can use the first intermediate insulating pattern 261, the second intermediate insulating pattern 271, and the protective layer 410 formed in the previous process as masks.

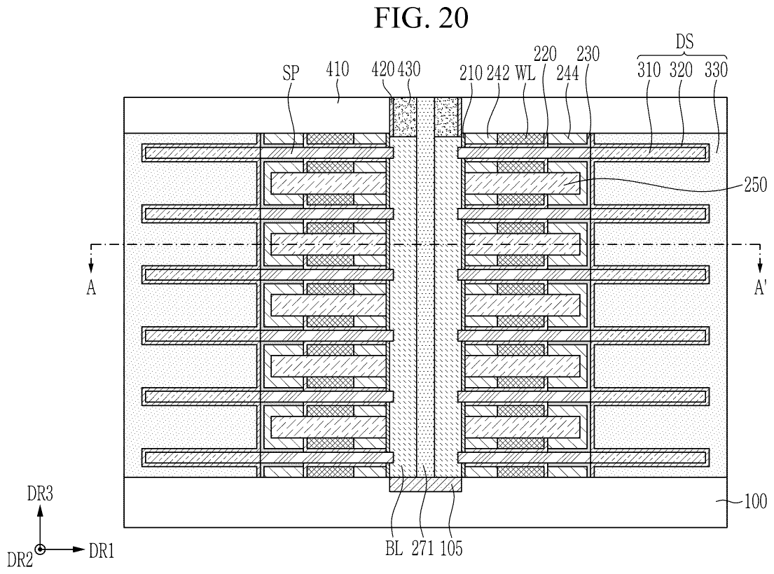

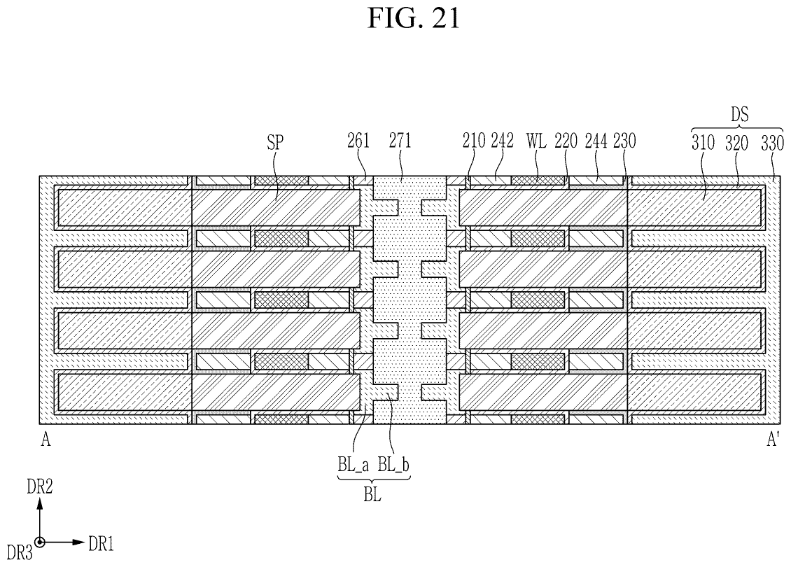

FIG. 20 is a cross-sectional view of a semiconductor device according to another embodiment. FIG. 21 is a plan view of the semiconductor device according to another embodiment, taken along line A-A′ of FIG. 20. Descriptions of parts that are substantially the same as those described previously will be omitted, and differences will be mainly explained.

Referring to FIG. 20 and FIG. 21, the bit line BL can be connected to the semiconductor patterns SP stacked in the third direction DR3. The plurality of bit lines BL can be positioned so as to be spaced apart along the first direction DR1 and the second direction DR2. The bit line BL can be connected to the semiconductor pattern SP positioned on one side rather than both sides based on the first direction DR1. The second intermediate insulating pattern 271 may be positioned between the plurality of bit lines BL. A pair of bit lines BL may be positioned spaced apart from each other in the first direction DR1, and the second intermediate insulating pattern 271 may be positioned between the pair of bit lines BL. The pair of bit lines BL spaced apart along the first direction DR1 can be positioned to face each other. The bit line BL may have a “T” shape in a plan view, but is not limited thereto.

The second intermediate insulating pattern 271 may be positioned between the plurality of pad electrodes 430. The second intermediate insulating pattern 271 can extend in the third direction DR3 from the field insulating layer 105 to the upper surface of the pad electrode 430. A pair of pad electrodes 430 may be positioned spaced apart from each other in the first direction DR1, and the second intermediate insulating pattern 271 may be positioned between the pair of pad electrodes 430. The pad electrodes 430 spaced apart along the first direction DR1 can be positioned to face each other. The pad electrode 430 may have a “T” shape in a plan view, but is not limited thereto.

The bit line BL may include the first portion BL_a and the second portion BL_b. Unlike the previous embodiment, the bit line BL may include one first portion BL_a and one second portion BL_b connected to the first portion BL_a.

The first portion BL_a may have a shape extending in the third direction DR3. The first portion BL_a can be connected to the plurality of semiconductor patterns SP stacked in the third direction DR3. The first portion BL_a may be positioned between the first intermediate insulating patterns 261. The first portion BL_a may have a larger width in the second direction DR2 than the second portion BL_b.

The first portion BL_a of the bit line BL can be positioned to overlap with the semiconductor pattern SP in the first direction DR1. The first portion BL_a can be positioned to overlap with the semiconductor pattern SP in the second direction DR2. However, this is not limited thereto, and in some embodiments, the first portion BL_a may be positioned so as not to overlap with the semiconductor pattern SP in the second direction DR2. The width of the first portion BL_a in the second direction DR2 may be greater than the width of the semiconductor pattern SP in the second direction DR2. However, this is not limited thereto, and in some embodiments, the width of the first portion BL_a in the second direction DR2 may be equal to or smaller than the width of the semiconductor pattern SP in the second direction DR2.

The second portion BL_b may have a shape extending in the third direction DR3. The second portion BL_b may have a smaller width in the second direction DR2 than the first portion BL_a. The second portion BL_b may have a shape extending from the first portion BL_a along the first direction DR1. The second intermediate insulating pattern 271 may be positioned between the plurality of second portions BL_b. The side wall of the second portion BL_b may be covered by the second intermediate insulating pattern 271.

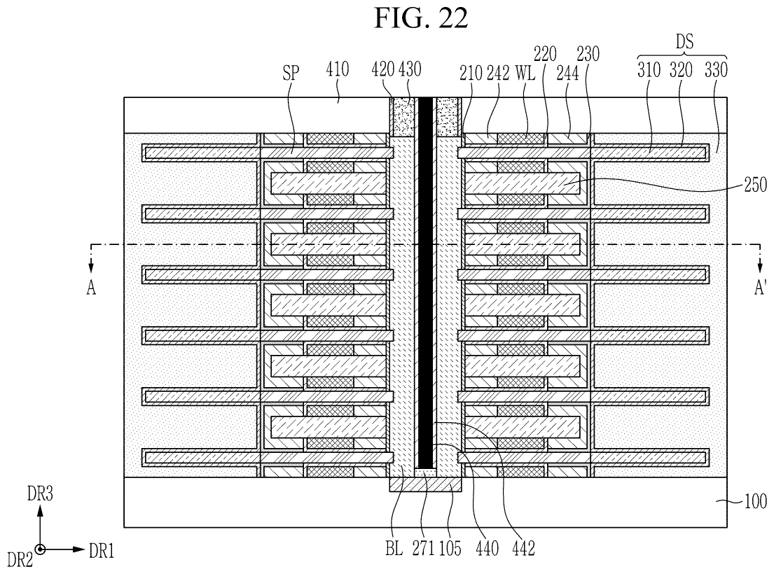

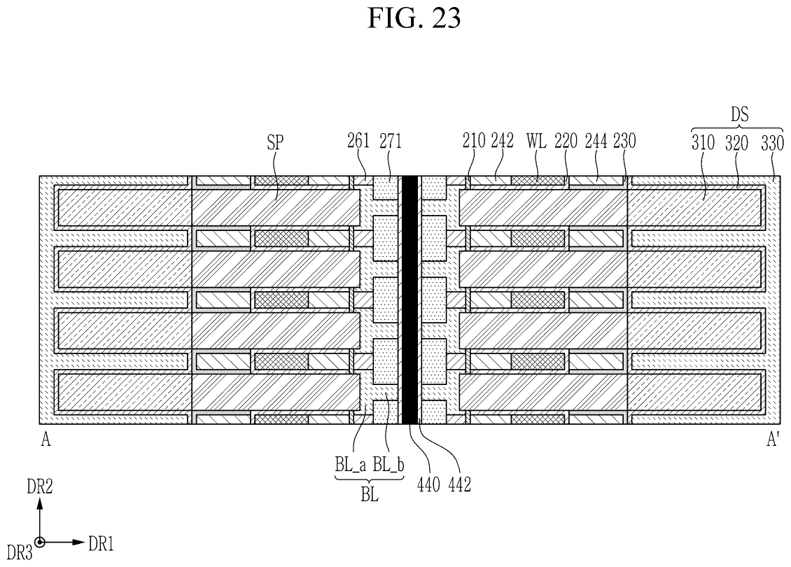

FIG. 22 is a cross-sectional view of a semiconductor device according to another embodiment. FIG. 23 is a plan view of the semiconductor device according to another embodiment, taken along line A-A′ of FIG. 22. Descriptions of parts that are substantially the same as those described previously will be omitted, and differences will be mainly explained.

Referring to FIG. 22 and FIG. 23, a shield pattern 440 may be positioned between the bit lines BL spaced apart from each other along the first direction DR1. The shield pattern 440 can be positioned on the substrate 100. The shield pattern 440 may be positioned on the field insulating layer 105. The shield pattern 440 may be positioned on the second intermediate insulating pattern 271. The shield pattern 440 can be positioned apart from the bit line BL. The shield pattern 440 can be positioned to be spaced apart from the bit line BL with a shield insulating layer 442 therebetween.

The shield pattern 440 may be positioned between the plurality of pad electrodes 430. The second intermediate insulating pattern 271 can extend in the third direction DR3 from the field insulating layer 105 to the upper surface of the pad electrode 430. The pair of pad electrodes 430 may be positioned spaced apart from each other in the first direction DR1, and the shield pattern 440 may be positioned between the pair of pad electrodes 430. The pad electrodes 430 spaced apart along the first direction DR1 can be positioned to face each other. The pad electrode 430 may have a “T” shape in a plan view, but is not limited thereto.

The shield pattern 440 can play a role in preventing electrical interference between the bit lines BL. The shield pattern 440 may include a conductive material. For example, the shield pattern 440 may include metal. For example, the shield pattern 440 may include a metal material such as titanium (Ti), tantalum (Ta), tungsten (W), copper (Cu), aluminum (Al), platinum (Pt), iridium (Ir), or ruthenium (Ru), but is not limited to.

The shield insulating layer 442 may be positioned on the shield pattern 440. The shield insulating layer 442 can be conformally placed on the shield pattern 440. The shield insulating layer 442 may be positioned between the shield pattern 440 and the bit line BL. The shield insulating layer 442 may be positioned between the shield pattern 440 and the second portion BL_b of the bit line BL. Also, the shield insulating layer 442 may be positioned between the shield pattern 440 and the pad electrode 430.

The shield insulating layer 442 may include an insulating material. By way of example, the shield insulating layer 442 may include at least one of silicon oxide (SiO), silicon nitride (SiN), and silicon oxynitride (SiON), but is not limited to.

The second intermediate insulating pattern 271 may be positioned between the shield pattern 440 and the field insulating layer 105. The second intermediate insulating pattern 271 may be positioned between bit lines BL spaced apart in the second direction DR2. A portion of the second intermediate insulating pattern 271 positioned below the shield pattern 440 may have a form extending in the second direction DR2, and a portion positioned between the bit lines BL may have a form extending in the third direction DR3.

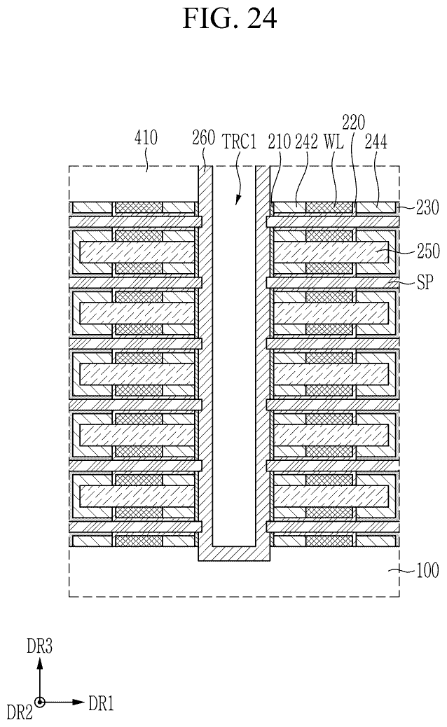

FIG. 24 to FIG. 33 are drawings for explaining a method of manufacturing a semiconductor device according to another embodiment. Descriptions of parts that are substantially the same as the manufacturing methods of the previously described embodiments will be omitted, and descriptions will be focused on the differences.

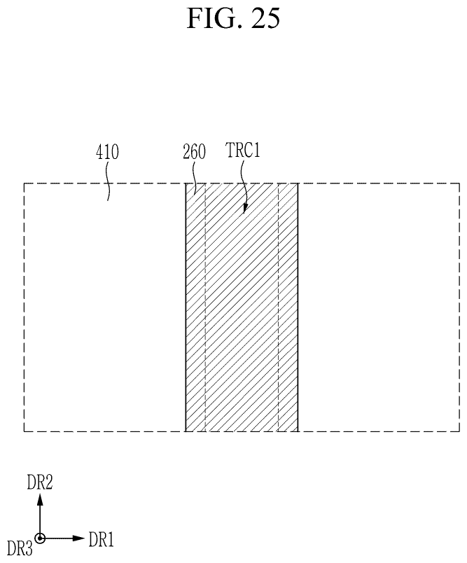

Referring to FIG. 24 and FIG. 25, the first intermediate insulating layer 260 can be formed within the first trench TRC1.

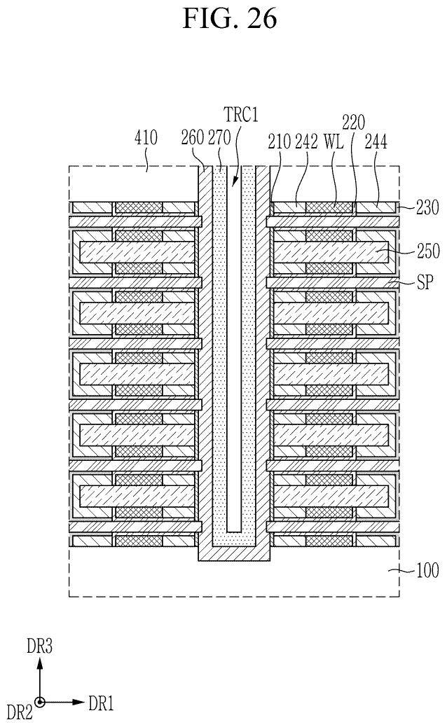

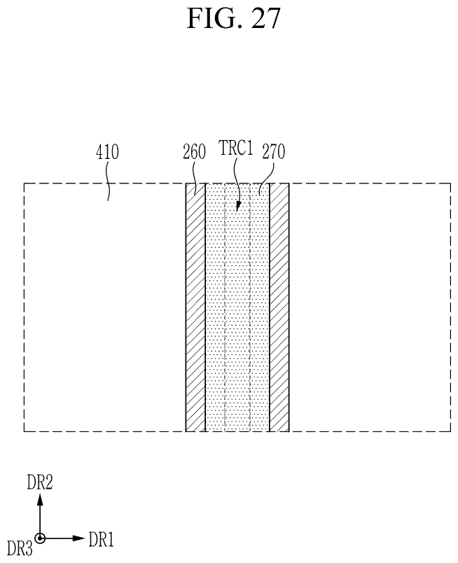

Next, referring to FIG. 26 and FIG. 27, the second intermediate insulating layer 270 can be formed on the first intermediate insulating layer 260. The second intermediate insulating layer 270 can be conformally formed on the first intermediate insulating layer 260 without filling the first trench TRC1. Accordingly, there may be empty space left within the first trench TRC1.

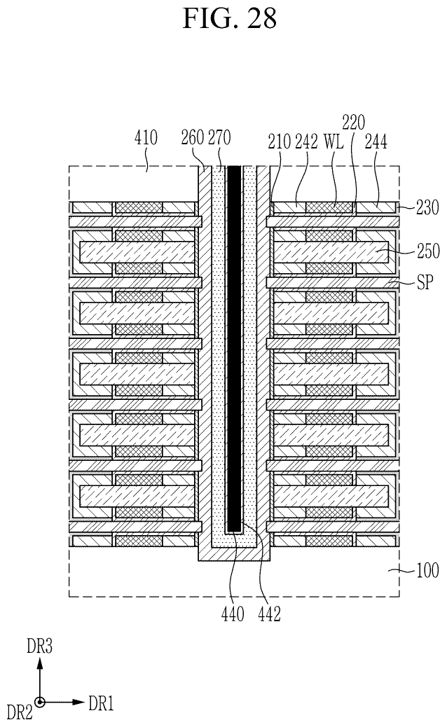

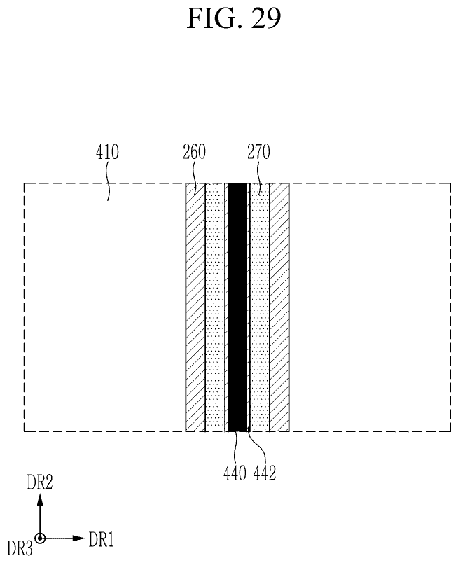

Next, referring to FIG. 28 and FIG. 29, a shield pattern 440 and the shield insulating layer 442 can be formed on the second intermediate insulating layer 270. The shield pattern 440 and the shield insulating layer 442 can fill the first trench TRC1.

For example, the shield insulating layer 442 can be conformally formed within the first trench TRC1 and on the second intermediate insulating layer 270, and then the shield pattern 440 can be formed to fill the first trench TRC1.

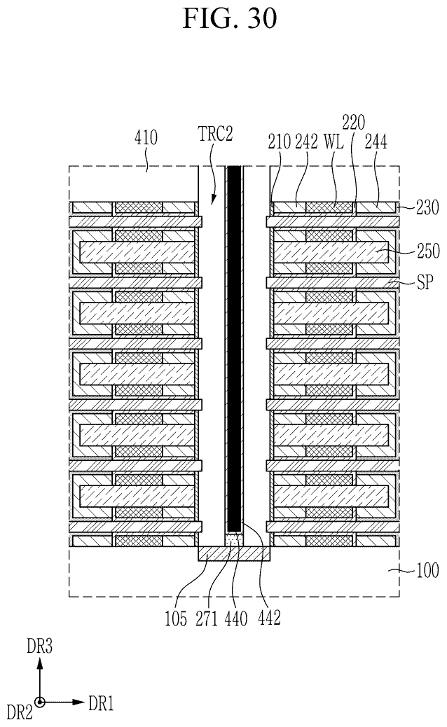

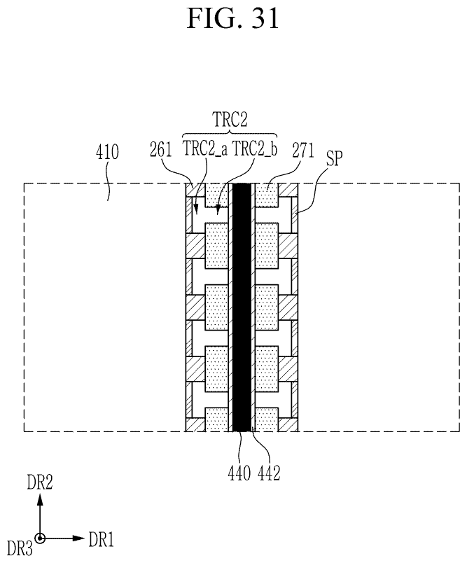

Next, referring to FIG. 30 and FIG. 31, patterning of the first intermediate insulating layer 260 and the second intermediate insulating layer 270 can be performed.

Patterning of the first intermediate insulating layer 260 can be performed in such a way that a portion of the first intermediate insulating layer 260 is removed. The field insulating layer 105 and a first intermediate insulating pattern 261 can be formed through patterning of the first intermediate insulating layer 260. The second trench TRC2 can be formed by patterning the first intermediate insulating layer 260 and the second intermediate insulating layer 270.

The second trench TRC2 may include the first region TRC2_a and the second region TRC2_b.

The first region TRC2_a may be positioned on one side of the second trench TRC2. The first region TRC2_a may be positioned between the first intermediate insulating patterns 261. The first region TRC2_a can be formed to overlap the first intermediate insulating pattern 261 in the second direction DR2. The other end of the semiconductor pattern SP can be exposed by the first region TRC2_a. The width of the first region TRC2_a in the second direction DR2 may be greater than the width of the second region TRC2_b in the second direction DR2.

The first region TRC2_a can be positioned to overlap with the semiconductor pattern SP in the second direction DR2. However, this is not limited thereto, and in some embodiments, the first region TRC2_a may be positioned so as not to overlap with the semiconductor pattern SP in the second direction DR2. The width of the first region TRC2_a in the second direction DR2 may be greater than the width of the semiconductor pattern SP in the second direction DR2. However, this is not limited thereto, and in some embodiments, the width of the first region TRC2_a in the second direction DR2 may be equal to or smaller than the width of the semiconductor pattern SP in the second direction DR2.

The second region TRC2_b may have a shape extending from the first region TRC2_a in the first direction DR1. The second region TRC2_b may be positioned between the second intermediate insulating patterns 271. The second region TRC2_b can be formed to overlap the second intermediate insulating pattern 271 in the second direction DR2. The width of the second region TRC2_b in the second direction DR2 may be smaller than the width of the first region TRC2_a in the second direction DR2.

The first region TRC2_a and the second region TRC2_b may have a form extending in the third direction DR3.

The second trench TRC2 may have a “T” shape in a plan view.

The field insulating layer 105 may be positioned on the bottom surface of the second trench TRC2. The field insulating layer 105 may be positioned on the substrate 100. The field insulating layer 105 may have a shape extending in the second direction DR2. The first intermediate insulating pattern 261 may be positioned on the substrate 100. The first intermediate insulating pattern 261 may be positioned on the field insulating layer 105. The first intermediate insulating pattern 261 may have a form extending in the third direction DR3. The second intermediate insulating pattern 271 may be positioned on the substrate 100. The second intermediate insulating pattern 271 may be positioned on the field insulating layer 105. The second intermediate insulating pattern 271 may have a form extending in the third direction DR3.

For example, the upper surfaces of the first intermediate insulating pattern 261 and the second intermediate insulating pattern 271 may be positioned at the same level as the upper surface of the protective layer 410.

The first intermediate insulating patterns 261 can be positioned to be spaced apart in the second direction DR2 by the second trench TRC2. The second intermediate insulating patterns 271 can be positioned to be spaced apart in the second direction DR2 by the second trench TRC2. An end of the semiconductor pattern SP can be exposed by the second trench TRC2.

No additional mask may be used to form the second trench TRC2. For example, the difference in the width of the first region TRC2_a and the second region TRC2_b of the second trench TRC2 in the second direction DR2 may be caused by a difference in the etching ratio of the first intermediate insulating layer 260 and the second intermediate insulating layer 270. However, without limitation thereto, for example, a photoresist material and a separate mask may be used for patterning the first intermediate insulating layer 260 and the second intermediate insulating layer 270. For example, a photoresist layer and a separate mask can be used to form the second trench TRC2. A wet etching process may be used for patterning the first intermediate insulating layer 260 and the second intermediate insulating layer 270, but is not limited thereto.

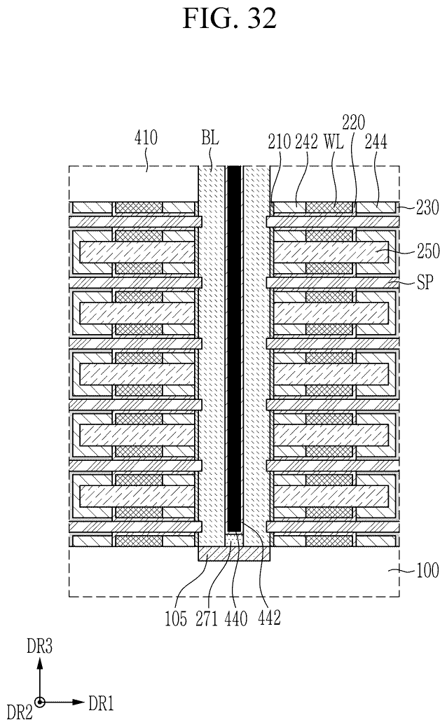

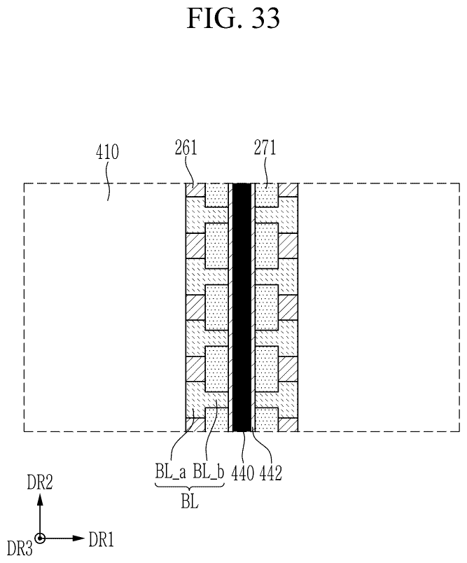

Next, referring to FIG. 32 and FIG. 33, the bit line BL can be formed within the second trench TRC2. The bit line BL may have a shape corresponding to the shape of the second trench TRC2. The bit line BL can have a “T” shape in a plan view.

The bit line BL may include the first portion BL_a and the second portion BL_b. The first portion BL_a can cover an end of the semiconductor pattern SP. The first portion BL_a may be covered by the first intermediate insulating pattern 261. For example, the first portion BL_a may be formed to overlap with the semiconductor pattern SP in the first direction DR1 and the third direction DR3, but may be formed to not overlap with the semiconductor pattern SP in the second direction DR2. The second portion BL_b may have a shape extending from the first portion BL_a in the first direction DR1. The second portion BL_b may be positioned between the second intermediate insulating patterns 271. The first portion BL_a and the second portion BL_b may have a shape extending in the third direction DR3. The width of the first portion BL_a in the second direction DR2 may be greater than the width of the second portion BL_b in the second direction DR2.

Although the embodiments of the present invention have been described in detail above, the scope of the present invention is not limited thereto, and various modifications and improvements made by those skilled in the art using the basic concept of the present invention defined in the following claims also fall within the scope of the present invention.

What is claimed is:

1. A semiconductor device comprising:
a substrate;
a semiconductor pattern positioned on the substrate and extending in a first direction parallel to an upper surface of the substrate;
a word line positioned on the semiconductor pattern and extending in a second direction, which is parallel to the upper surface of the substrate and intersects the first direction;
a bit line connected to one end of the semiconductor pattern and extending in a third direction perpendicular to the upper surface of the substrate; and
a data storage element connected to another end of the semiconductor pattern,
wherein the bit line comprises a first portion connected to the semiconductor pattern and a second portion extending in the first direction from the first portion, and a width of the first portion in the second direction is greater than a width of the second portion in the second direction.

2. The semiconductor device of claim 1, further comprising a first intermediate insulating pattern in contact with the first portion of the bit line, and a second intermediate insulating pattern in contact with the second portion of the bit line.

3. The semiconductor device of claim 2, wherein the first intermediate insulating pattern and the second intermediate insulating pattern have different compositional ratios.

4. The semiconductor device of claim 1, further comprising a field insulating layer positioned between the substrate and the bit line.

5. The semiconductor device of claim 1, wherein the bit line comprises a plurality of first portions positioned on opposite sides of the second portion, and the bit line has an H-shaped structure in a plan view.

6. The semiconductor device of claim 1, further comprising a shield pattern positioned on one side of the bit line.

7. The semiconductor device of claim 6, further comprising a shield insulating layer positioned between the shield pattern and the bit line.

8. The semiconductor device of claim 6, wherein the shield pattern extends in the second direction and the third direction.

9. The semiconductor device of claim 1, wherein the bit line has a T-shaped structure in a plan view.

10. The semiconductor device of claim 1,
further comprising a pad electrode disposed above the bit line and electrically connected to the bit line,
wherein the pad electrode has a planar shape substantially identical to a planar shape of the bit line.

11. A semiconductor device comprising:
a substrate;
a first semiconductor pattern and a second semiconductor pattern positioned on the substrate and extending in a first direction parallel to an upper surface of the substrate;
a first word line and a second word line extending in a second direction, which is parallel to the upper surface of the substrate and intersects the first direction, and positioned to overlap the first semiconductor pattern and the second semiconductor pattern, respectively;
a first bit line to which the first semiconductor pattern and the second semiconductor pattern are connected on opposite sides in the first direction, and a second bit line positioned apart from the first bit line in the second direction; and
a pair of first intermediate insulating patterns positioned between the first bit line and the second bit line, and a second intermediate insulating pattern positioned between the pair of first intermediate insulating patterns.

12. The semiconductor device of claim 11, wherein a width of the first intermediate insulating pattern in the second direction is greater than a width of the second intermediate insulating pattern in the second direction.

13. The semiconductor device of claim 11, wherein the first bit line and the second bit line each comprise a first portion in contact with the first intermediate insulating pattern and a second portion in contact with the second intermediate insulating pattern.

14. The semiconductor device of claim 11, wherein the first bit line and the second bit line are positioned to overlap the second intermediate insulating pattern in the first direction.

15. The semiconductor device of claim 11, wherein a width of the pair of first intermediate insulating patterns in the first direction is identical.

16. A semiconductor device comprising:
a substrate;
semiconductor patterns positioned on the substrate and extending in a first direction parallel to an upper surface of the substrate;
word lines positioned on the semiconductor patterns and extending in a second direction, which is parallel to the upper surface of the substrate and intersects the first direction;
a pair of bit lines connected to one end of the semiconductor patterns, extending in a third direction perpendicular to the upper surface of the substrate, and spaced apart from each other in the first direction; and
data storage elements connected to another end of the semiconductor patterns,
wherein each bit line comprises a first portion positioned on one side of the bit line and connected to the semiconductor patterns stacked in the third direction, and a second portion extending in the first direction from the first portion, and a width of the first portion in the second direction is greater than a width of the second portion in the second direction.

17. The semiconductor device of claim 16, wherein each bit line has a T-shaped structure in a plan view.

18. The semiconductor device of claim 16, further comprising a shield pattern positioned between the pair of bit lines.

19. The semiconductor device of claim 18, further comprising a shield insulating layer positioned between the shield pattern and the pair of bit lines.

20. The semiconductor device of claim 16, further comprising a first intermediate insulating pattern in contact with the first portion of each bit line and a second intermediate insulating pattern in contact with the second portion of each bit line.
